(19) United States
(12) Patent Application Publication
(10) Pub. No.: US 2011/0133332 A1
(43) Pub. Date: Jun. 9, 2011

(54) Package substrate and method of fabricating the same

(75) Inventors: Seon Jae Mun, Suwon (KR); Dae Young Lee, Ansan (KR); Tae Joon Chung, Seoul (KR); Dong Gyu Lee, Suwon (KR); Jin Won Choi, Yongin (KR)

(73) Assignee: Samsung Electro-Mechanics Co., Ltd., Suwon (KR)

(21) Appl. No.: 12/926,279

(22) Filed: Nov. 5, 2010

(30) Foreign Application Priority Data
Dec. 8, 2009 (KR) 10-2009-0121099

(51) Int. Cl. H01L 23/498; H01L 21/60

(52) U.S. Cl. 257/737; 438/116; 257/E23.069; 257/E21.508

(57) ABSTRACT

There is provided a package substrate allowing for enhanced reliability by improving the structure of a solder bump and a method of fabricating the same. The package substrate includes: a substrate having at least one conductive pad; an insulating layer provided on the substrate and having an opening to expose the conductive pad; a post terminal provided on the conductive pad inside the opening; and a solder bump provided on the post terminal and having an angle between a bottom surface and a side surface thereof ranging from 80° to 120°.

### CROSS-REFERENCE TO RELATED APPLICATIONS

This application claims the priority of Korean Patent Application No. 10-2009-0121099 filed on Dec. 8, 2009, in the Korean Intellectual Property Office, the disclosure of which is incorporated herein by reference.

### BACKGROUND OF THE INVENTION

1. Field of the Invention

The present invention relates to a package substrate and a method of fabricating the same, and more particularly, to a package substrate allowing for enhanced reliability by improving the structure of a solder bump and a method of fabricating the same.

2. Description of the Related Art

A general semiconductor package employs a soldering method using a lead frame when mounted on a printed circuit board (PCB). Such a soldering method using the lead frame is advantageous in facilitating its process and having superior reliability, while it is disadvantageous in terms of electrical characteristics since an electrical signal transferring length between a semiconductor chip and the PCB is long.

A flip chip package, which is proposed in order to solve the above problem, simplifies a circuit design since the positions of input/output pads on an internal circuit of a semiconductor chip are determined using a bonding process allowing for high-density packaging, reduces consumed power due to a reduction of resistance by a circuit wire, has superior electrical characteristics since the path of an electrical signal becomes short and the operating speed of the semiconductor package is enhanced, has superior thermal characteristics since the rear surface of the semiconductor chip is exposed to the outside, is compact, and is easily bonded due to solder self-alignment characteristics.

An electrical connection between a semiconductor chip and a substrate in the flip chip package is made by a direct contact between protruding bumps formed on the input/output pads of the semiconductor chip, such as a solder bump, a stud bump, a bump formed by a plating method or a screen printing method, or a bump formed by depositing and etching a metal, and bump pads formed on the substrate.

In the flip chip package, an under-fill is formed between the semiconductor chip and the substrate. The under-fill prevents deformations and cracks in a solder joint, like plastic strain caused by a difference in thermal expansion coefficients between the semiconductor chip and the substrate, whereby the package obtains stable electrical characteristics.

In a substrate including bump pads for a conventional flip chip package, when a solder resist is applied and patterned on the substrate including the bump pads formed of metal such as copper (Cu) in direct contact with bumps formed on input/output pads of a semiconductor chip, part of each of the bump pads is exposed to the outside. Then, a solder paste is applied and reflowed on the exposed bump pads.

Here, the bump pads formed on the substrate of the conventional flip chip package have a low height, and accordingly the height of solder joints is low, whereby temperature circulation is reduced.

Also, since the bump pads have a low height, it is difficult to perform an under-fill filling using a liquid under-fill material in the forming of the under-fill between the semiconductor chip and the substrate, thereby degrading the operational efficiency of the under-fill process.

### SUMMARY OF THE INVENTION

An aspect of the present invention provides a package substrate allowing for enhanced reliability by improving the structure of a solder bump and a method of fabricating the same.

According to an aspect of the present invention, there is provided a package substrate including: a substrate having at least one conductive pad; an insulating layer provided on the substrate and having an opening to expose the conductive pad; a post terminal provided on the conductive pad inside the opening; and a solder bump provided on the post terminal and having an angle between a bottom surface and a side surface thereof ranging from 80° to 120°.

The angle may range from 90° to 110°.

The post terminal may further include a plating seed layer at a bottom thereof.

The post terminal may be formed by electroplating.

The solder bump may be formed of at least one selected from the group consisting of tin-lead, tin-bismuth, tin-copper, and tin-copper-silver alloys.

According to another aspect of the present invention, there is provided a method of fabricating a package substrate, the method including: forming an insulating layer having a first opening to expose a conductive pad prepared on a substrate; forming a first dry film pattern having a second opening on the insulating layer, the second opening being in communication with the first opening and having a greater width than the first opening; forming a post terminal inside the first and second openings; forming a second dry film pattern having a third opening on the first dry film pattern, the third opening having a greater width than the second opening; providing a solder paste into the third opening; and forming a solder bump having an angle between a bottom surface and a side surface thereof ranging from 80° to 120° by ref lowing the solder paste.

The angle may range from 90° to 110°.

The method may further include, before the forming of the post terminal, forming a plating seed layer on the insulating layer, and forming the first dry film pattern on the plating seed layer for the forming of the post terminal.

The forming of the first dry film pattern may include forming a first dry film resist on the insulating layer to cover the first opening, and forming the first dry film pattern by exposing the first dry film resist to light and developing the first dry film resist.

The forming of the second dry film pattern may include forming a second dry film resist on the first dry film pattern to cover the post terminal, and forming the second dry film pattern by exposing the second dry film resist to light and developing the second dry film resist.

The post terminal may be formed by electroplating.

The solder bump may be formed of at least one selected from the group consisting of tin-lead, tin-bismuth, tin-copper, and tin-copper-silver alloys.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic cross-sectional view illustrating a package substrate according to an exemplary embodiment of the present invention; and

FIGS. 2A through 2H are schematic cross-sectional views illustrating processes of fabricating a package substrate according to an exemplary embodiment of the present invention.

### DETAILED DESCRIPTION OF THE PREFERRED EMBODIMENT

Exemplary embodiments of the present invention will now be described in detail with reference to the accompanying drawings.

The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions may be exaggerated for clarity, and the same reference numerals will be used throughout to designate the same or like components.

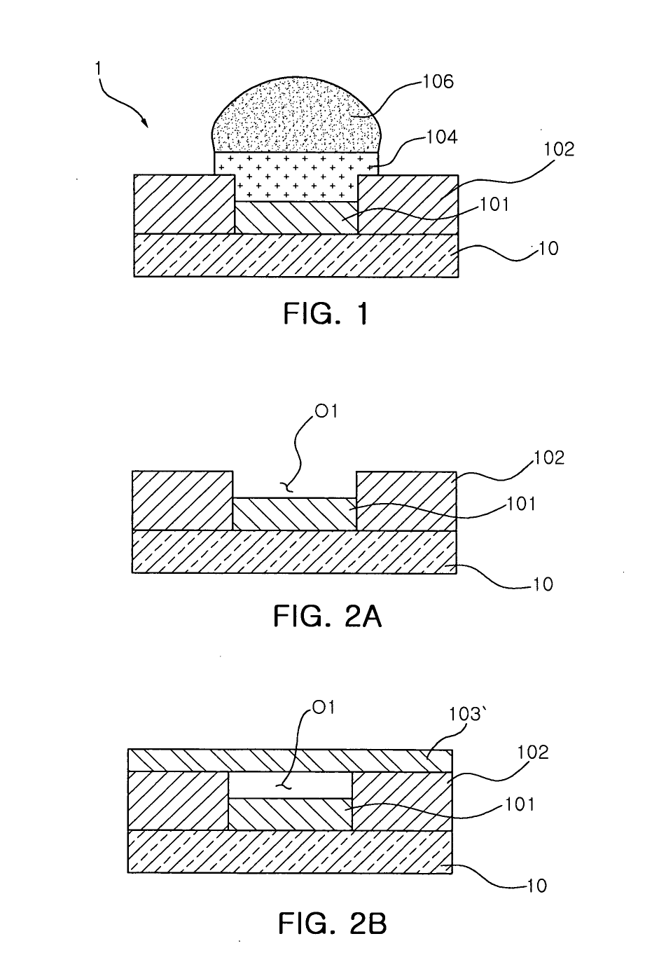

Hereinafter, a package substrate according to an exemplary embodiment of the present invention will be described with reference to FIG. 1.

FIG. 1 is a schematic cross-sectional view illustrating a package substrate according to an exemplary embodiment of the present invention.

A package substrate 1 according to this embodiment includes a substrate 10 having at least one conductive pad 101, an insulating layer 102 formed on the substrate 10 and having an opening to expose the conductive pad 101, a post terminal 104 formed on the conductive pad 101 inside the opening, and a solder bump 106 formed on the post terminal 104 and having an angle between a bottom surface and a side surface thereof ranging from 80° to 120°.

The post terminal 104 may further include a plating seed layer (not shown) at the bottom thereof. The plating seed layer may be a chemical copper plating layer formed by electroless plating. The plating seed layer serves as an electrode for the post terminal 104 formed by electroplating.

The post terminal 104 may be formed by electroplating and disposed on the conductive pad 101 inside the opening. The post terminal 104 may be formed of copper, or an alloy of tin and copper. However, the materials of the post terminal 104 are not limited thereto.

The solder bump 106 is formed on the post terminal 104 and has an angle between the bottom surface and the side surface thereof ranging from 80° to 120°. Here, the angle between the bottom surface and the side surface of the solder bump 106 may range from 90° to 110°. Also, the solder bump 106 may be formed of at least one selected from the group consisting of tin-lead, tin-bismuth, tin-copper, and tin-copper-silver alloys.

As described above, there is provided a package substrate having enhanced reliability by improving the structure of the solder bump according to this embodiment.

As the height of a solder joint increases by improving the structure of the solder bump, a package substrate allowing for a fine pitch and facilitating an under-fill process may be provided.

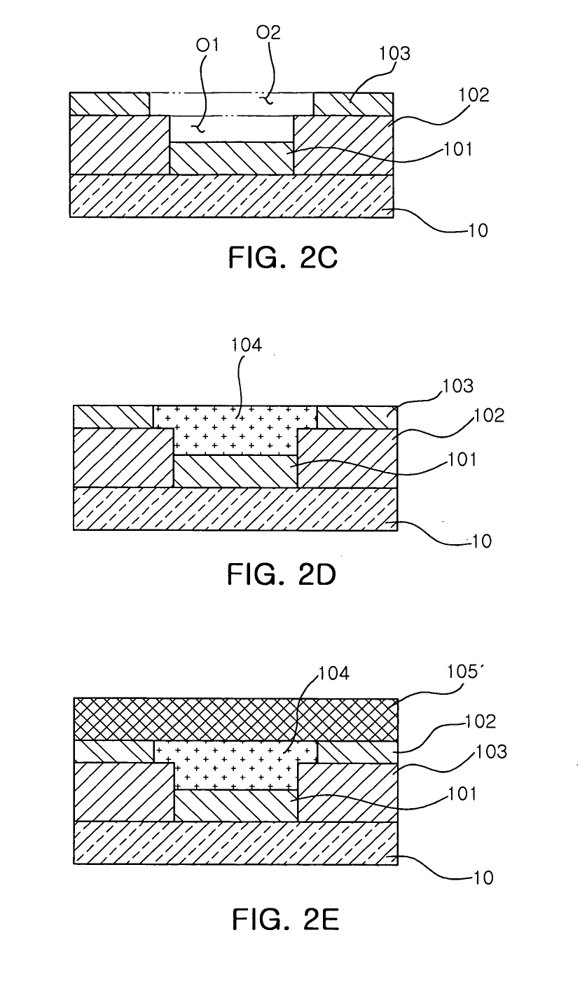

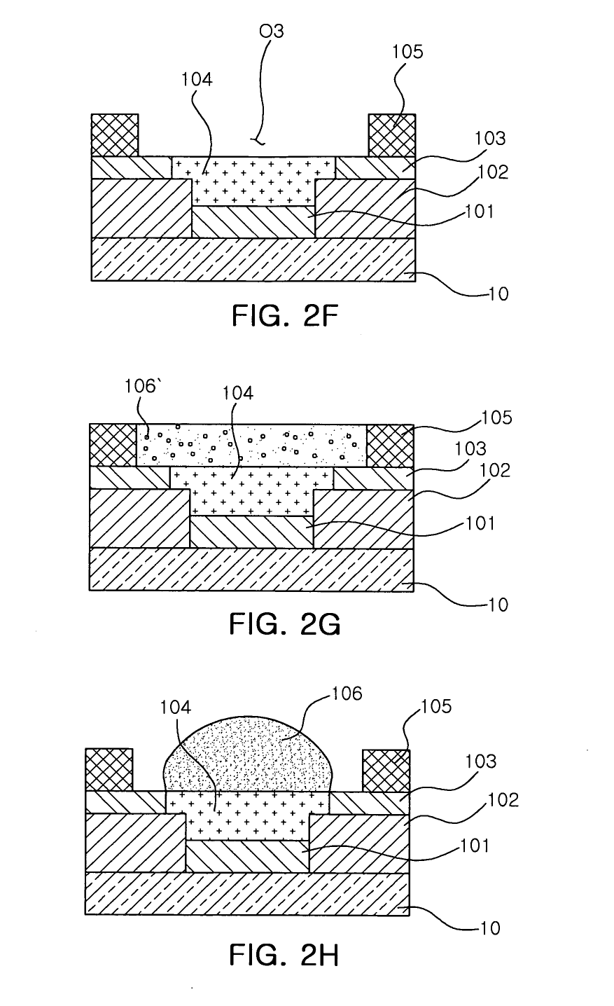

Hereinafter, a method of fabricating a package substrate according to an exemplary embodiment of the present invention will be described with reference to FIGS. 2A through 2H.

FIGS. 2A through 2H are schematic cross-sectional views illustrating processes of fabricating a package substrate according to an exemplary embodiment of the present invention.

A method of fabricating the package substrate 1 according to this embodiment includes: forming the insulating layer 102 having a first opening 01 to expose the conductive pad 101 prepared on the substrate 10; forming a first dry film pattern 103 having a second opening 02 on the insulating layer 102, the second opening 02 being in communication with the first opening 01 and having a greater width than the first opening 01; forming the post terminal 104 inside the first and second openings 01 and 02; forming a second dry film pattern 105 having a third opening 03 on the first dry film pattern 103, the third opening 03 having a greater width than the second opening 02; providing a solder paste 106′ into the third opening 03; and forming a solder bump 106 having an angle between a bottom surface and a side surface thereof ranging from 80° to 120° by reflowing the solder paste 106′.

As shown in FIG. 2A, the insulating layer 102 having the first opening 01 is formed such that the first opening 01 exposes the conductive pad 101 that is prepared on the substrate 10. The insulating layer 102 may be formed of photosensitive solder resist. The solder resist is applied, exposed to light, and developed, thereby forming the insulating layer 102.

Next, as shown in FIG. 2B, a first dry film resist 103′ is formed on the insulating layer 102 to cover the first opening 01. The first dry film resist 103′ is exposed to light and developed, thereby forming the first dry film pattern 103 having the second opening 02 of a greater width than the first opening 01 as shown in FIG. 2C.

After that, the plating seed layer (not shown) is formed on the insulating layer 102 and the first dry film pattern 103 that have the first and second openings 01 and 02, respectively. The plating seed layer may be a chemical copper plating layer formed by electroless plating. The plating seed layer serves as an electrode for the post terminal 104 formed by electroplating.

Then, as shown in FIG. 2D, the post terminal 104 may be formed inside the first and second openings 01 and 02. As described above, the post terminal 104 may be formed by electroplating. The post terminal 104 may be formed of copper, or an alloy of tin and copper. However, the materials of the post terminal 104 are not limited thereto.

Then, as shown in FIG. 2E, a second dry film resist 105′ is formed on the first dry film pattern 103 to cover the post terminal 104. After that, the second dry film resist 105′ is exposed to light and developed, thereby forming the second dry film pattern 105 having the third opening 03 of a greater width than the second opening 02 as shown in FIG. 2F.

Then, as shown in FIG. 2G, the solder paste 106′ is printed inside the third opening 03.

Then, as shown in FIG. 2H, the solder paste 106′ is reflowed to form the solder bump 106 having an angle between the bottom surface and the side surface thereof ranging from 80° to 120°. Here, the angle between the bottom surface and the side surface of the solder bump 106 may range from 90° to 110°.

By forming the second dry film pattern 105 having the third opening 03 of a greater width than the second opening 02 and printing the solder paste 106′ inside the third opening 03, an amount of solder paste 106′ greater than that used in a conventional process can be printed. Therefore, when the solder bump 106 is formed using the increased amount of solder paste 106′ by the reflow process, the solder bump 106 having an angle between the bottom surface and the side surface thereof ranging from 80° to 120°, preferably ranging from 90° to 110° may be formed.

Also, the solder bump 106 may be formed of at least one selected from the group consisting of tin-lead, tin-bismuth, tin-copper, and tin-copper-silver alloys.

As set forth above, according to exemplary embodiments of the invention, a package substrate having enhanced reliability by improving the structure of a solder bump and a method of fabricating the same may be provided.

Further, as the height of a solder joint increases by improving the structure of a solder bump, a package substrate allowing for a fine pitch and facilitating an under-fill process and a method of fabricating the same may be provided.

While the present invention has been shown and described in connection with the exemplary embodiments, it will be apparent to those skilled in the art that modifications and variations can be made without departing from the spirit and scope of the invention as defined by the appended claims.

What is claimed is:

1. A package substrate comprising:
a substrate having at least one conductive pad;
an insulating layer provided on the substrate and having an opening to expose the conductive pad;
a post terminal provided on the conductive pad inside the opening; and
a solder bump provided on the post terminal and having an angle between a bottom surface and a side surface thereof ranging from 80° to 120°.

2. The package substrate of claim 1, wherein the angle ranges from 90° to 110°.

3. The package substrate of claim 1, wherein the post terminal further comprises a plating seed layer at a bottom thereof.

4. The package substrate of claim 3, wherein the post terminal is formed by electroplating.

5. The package substrate of claim 1, wherein the solder bump is formed of at least one selected from the group consisting of tin-lead, tin-bismuth, tin-copper, and tin-copper-silver alloys.

6. A method of fabricating a package substrate, the method comprising:
forming an insulating layer having a first opening to expose a conductive pad prepared on a substrate;
forming a first dry film pattern having a second opening.
on the insulating layer, the second opening being in communication with the first opening and having a greater width than the first opening;
forming a post terminal inside the first and second openings;
forming a second dry film pattern having a third opening on the first dry film pattern, the third opening having a greater width than the second opening;
providing a solder paste into the third opening; and
forming a solder bump having an angle between a bottom surface and a side surface thereof ranging from 80° to 120° by reflowing the solder paste.

7. The method of claim 6, wherein the angle ranges from 90° to 110°.

8. The method of claim 6, further comprising, before the forming of the post terminal, forming a plating seed layer on the insulating layer, and forming the first dry film pattern on the plating seed layer for the forming of the post terminal.

9. The method of claim 8, wherein the forming of the first dry film pattern comprises:
forming a first dry film resist on the insulating layer to cover the first opening; and
forming the first dry film pattern by exposing the first dry film resist to light and developing the first dry film resist.

10. The method of claim 8, wherein the forming of the second dry film pattern comprises:
forming a second dry film resist on the first dry film pattern to cover the post terminal; and
forming the second dry film pattern by exposing the second dry film resist to light and developing the second dry film resist.

11. The method of claim 8, wherein the post terminal is formed by electroplating.

12. The method of claim 6, wherein the solder bump is formed of at least one selected from the group consisting of tin-lead, tin-bismuth, tin-copper, and tin-copper-silver alloys.
